(19) United States
(12) Patent Application Publication
(10) Pub. No.: US 2023/0269923 A1
(43) Pub. Date: Aug. 24, 2023

(54) SEMICONDUCTOR MEMORY DEVICE

(71) Applicant: Unisantis Electronics Singapore Pte. Ltd., Singapore (SG)

(72) Inventors: Nozomu HARADA, Tokyo (JP); Masakazu Kakumu, Tokyo (JP); Koji Sakui, Tokyo (JP)

(21) Appl. No.: 18/172,097

(22) Filed: Feb. 21, 2023

(30) Foreign Application Priority Data
Feb. 22, 2022 (WO) PCT/JP2022/007375

(51) Int. Cl. H10B 12/00

(52) U.S. Cl. CPC H10B 12/20

(57) ABSTRACT

A dynamic flash memory cell and a fin transistor are formed on a P layer substrate 10a. The dynamic flash memory cell includes a first insulating layer 11a, a fin P layer 25, N⁺ layers 35ba and 35bb, a gate insulating layer 27b, and gate conductor layers 30ba and 30bb; the fin transistor includes a fin P layer 22 including fin P layers 15a and 15b, N⁺ layers 35aa and 35ab, a gate insulating layer 27a, and a gate conductor layer 30a; in a perpendicular direction, a top portion of the fin P layer 25 is positioned close to or higher than a top portion of the fin P layer 15a, bottom portions of the gate insulating layers 27a and 27b are positioned close to each other, and a bottom portion of the fin semiconductor layer 15b is positioned within the P layer substrate 10a.

### CROSS REFERENCE TO RELATED APPLICATIONS

This application claims priority to PCT/JP2022/007375, filed Feb. 22, 2022, the entire content of which is incorporated herein by reference.

### BACKGROUND OF THE INVENTION

### 1. Field of the Invention

The present invention relates to a semiconductor memory device.

### 2. Description of the Related Art

In recent years, in development of the LSI (Large Scale Integration) technology, there has been a demand for memory elements having a higher degree of integration and higher performance.

In the ordinary planar MOS transistor, the channel extends, along the upper surface of the semiconductor substrate, in the horizontal direction. By contrast, the channel of the SGT extends in a direction perpendicular to the upper surface of the semiconductor substrate (refer to, for example, Japanese Unexamined Patent Application Publication No. 2-188966 and Hiroshi Takato, Kazumasa Sunouchi, Naoko Okabe, Akihiro Nitayama, Katsuhiko Hieda, Fumio Horiguchi, and Fujio Masuoka: IEEE Transaction on Electron Devices, Vol. 38, No. 3, pp. 573-578 (1991)). For this reason, the SGT enables, compared with the planar MOS transistor, an increase in the density of the semiconductor device. Use of this SGT as a select transistor enables a higher degree of integration in, for example, a DRAM (Dynamic Random Access Memory, refer to, for example, H. Chung, H. Kim, H. Kim, K. Kim, S. Kim, K. W. Song, J. Kim, Y. C. Oh, Y. Hwang, H. Hong, G. Jin, and C. Chung: “4F2 DRAM Cell with Vertical Pillar Transistor (VPT)”, 2011 Proceeding of the European Solid-State Device Research Conference, (2011)) to which a capacitor is connected, a PCM (Phase Change Memory, refer to, for example, H. S. Philip Wong, S. Raoux, S. Kim, Jiale Liang, J. R. Reifenberg, B. Rajendran, M. Asheghi and K. E. Goodson: “Phase Change Memory”, Proceeding of IEEE, Vol. 98, No 12, December, pp. 2201-2227 (2010)) to which a resistance change element is connected, an RRAM (Resistive Random Access Memory, refer to, for example, K. Tsunoda, K. Kinoshita, H. Noshiro, Y. Yamazaki, T. Iizuka, Y. Ito, A. Takahashi, A. Okano, Y. Sato, T. Fukano, M. Aoki, and Y. Sugiyama: “Low Power and high Speed Switching of Ti-doped NiO ReRAM under the Unipolar Voltage Source of less than 3V”, IEDM (2007)), and an MRAM (Magneto-resistive Random Access Memory, refer to, for example, W. Kang, L. Zhang, J. Klein, Y. Zhang, D. Ravelosona, and W. Zhao: “Reconfigurable Codesign of STT-MRAM Under Process Variations in Deeply Scaled Technology”, IEEE Transaction on Electron Devices, pp. 1-9 (2015)) in which a current is used to change the orientation of the magnetic spin to change the resistance. In addition, there is a capacitor-less DRAM memory cell constituted by a single MOS transistor (refer to M. G. Ertosun, K. Lim, C. Park, J. Oh, P. Kirsch, and K. C. Saraswat: “Novel Capacitorless Single-Transistor Charge-Trap DRAM (1T CT DRAM) Utilizing Electron”, IEEE Electron Device Letter, Vol. 31, No. 5, pp. 405-407 (2010), and J. Wan, L. Rojer, A. Zaslaysky, and S. Critoloveanu: “A Compact Capacitor-Less High-Speed DRAM Using Field Effect-Controlled Charge Regeneration”, Electron Device Letters, Vol. 35, No. 2, pp. 179-181 (2012)), for example. The present application relates to a dynamic flash memory that does not include resistance change elements or capacitors and can be constituted by a MOS transistor alone.

For the above-described capacitor-less DRAM memory cell constituted by a single MOS transistor, FIGS. 11A to 11D illustrate the write operation, FIGS. 12A and 12B illustrate a problem during the operation, and FIGS. 13A to 13C illustrate the read operation (refer to J. Wan, L. Rojer, A. Zaslaysky, and S. Critoloveanu: “A Compact Capacitor-Less High-Speed DRAM Using Field Effect-Controlled Charge Regeneration”, Electron Device Letters, Vol. 35, No. 2, pp. 179-181 (2012), T. Ohsawa, K. Fujita, T. Higashi, Y. Iwata, T. Kajiyama, Y. Asao, and K. Sunouchi: “Memory design using a one-transistor gain cell on SOI”, IEEE JSSC, vol. 37, No. 11, pp 1510-1522 (2002), T. Shino, N. Kusunoki, T. Higashi, T. Ohsawa, K. Fujita, K. Hatsuda, N. Ikumi, F. Matsuoka, Y. Kajitani, R. Fukuda, Y. Watanabe, Y. Minami, A. Sakamoto, J. Nishimura, H. Nakajima, M. Morikado, K. Inoh, T. Hamamoto, A. Nitayama: “Floating Body RAM Technology and its Scalability to 32 nm Node and Beyond”, IEEE IEDM (2006), and E. Yoshida and T. Tanaka: “A Design of a Capacitorless 1T-DRAM Cell Using Gate-Induced Drain-Leakage (GIDL) Current for Low-Power and High-Speed Embedded Memory”, IEEE IEDM (2003)).

FIGS. 11A to 11D illustrate the write operation of the DRAM memory cell. FIG. 11A illustrates the “1” write state. This memory cell is formed on an SOI substrate 100, and is constituted by a source N⁺ layer 103 (hereafter, semiconductor regions containing donor impurities at high concentrations will be referred to as “N⁺ layers”) to which a source line SL is connected, a drain N⁺ layer 104 to which a bit line BL is connected, a gate conductive layer 105 to which a word line WL is connected, and a floating body (Floating Body) 102 of a MOS transistor 110a; thus, the capacitor-less DRAM memory cell is constituted by the single MOS transistor 110a. Note that the floating body 102 is in contact with the immediately underlying layer, the SiO₂ layer 101 of the SOI substrate 100. In the memory cell constituted by the single MOS transistor 110a, in order to write “1”, the MOS transistor 110a is operated in the saturation region. Specifically, an electron channel 107 extending from the source N⁺ layer 103 has a pinch-off point 108 and does not reach the drain N⁺ layer 104 to which the bit line is connected. Thus, when the MOS transistor 110a is operated such that the bit line BL connected to the drain N⁺ layer 104 and the word line WL connected to the gate conductive layer 105 are set at high voltages, and the gate voltage is set at about ½ of the drain voltage, the electric field strength becomes maximum at the pinch-off point 108 near the drain N⁺ layer 104. As a result, accelerated electrons flowing from the source N⁺ layer 103 to the drain N⁺ layer 104 collide with the Si lattice, and the kinetic energy lost at this time causes generation of electron-hole pairs. Most of the generated electrons (not shown) reach the drain N⁺ layer 104. A very small portion of the electrons, very hot electrons jump over a gate oxide film 109, to reach the gate conductive layer 105. Holes 106 generated at the same time charge the floating body 102. In this case, the generated holes contribute, in the floating body 102 formed of P-type Si, as an increment of the majority carrier. When the floating body 102 is filled with the generated holes 106 and the voltage of the floating body 102 becomes higher than that of the source N⁺ layer 103 by Vb or more, holes further generated are discharged to the source N⁺ layer 103. Vb is the built-in voltage of the PN junction between the source N⁺ layer 103 and the P layer floating body 102, and is about 0.7 V. FIG. 11B illustrates a state in which the floating body 102 is charged to saturation with the holes 106 generated.

Hereinafter, with reference to FIG. 11C, the “0” write operation of the memory cell 110 will be described. For the common select word line WL, there are randomly a memory cell 110a to which “1” is written and a memory cell 110b to which “0” is written. FIG. 11C illustrates a state of a rewrite from a “1” write state to a “0” write state. In order to write “0”, the voltage of the bit line BL is set to a negative bias and the PN junction between the drain N⁺ layer 104 and the P layer floating body 102 is forward biased. As a result, the holes 106 generated in advance in the floating body 102 in the previous cycle flow to the drain N⁺ layer 104 connected to the bit line BL. Completion of the write operation provides two states of memory cells that are the memory cell 110a filled with the generated holes 106 (FIG. 11B) and the memory cell 110b from which the generated holes have been discharged (FIG. 11C). In the memory cell 110a filled with the holes 106, the floating body 102 has a higher potential than the floating body 102 not having generated holes. Thus, the threshold voltage of the memory cell 110a becomes lower than the threshold voltage of the memory cell 110b. This state is illustrated in FIG. 11D.

Hereinafter, a problem in the operation of the memory cell constituted by a single MOS transistor will be described with reference to FIGS. 12A and 12B. As illustrated in FIG. 12A, the capacitance C_{FB} of the floating body 102 is the sum of the capacitance C_{WL} between the gate to which the word line is connected and the floating body 102, the junction capacitance C_{SL} of the PN junction between the source N⁺ layer 103 to which the source line is connected and the floating body 102, and the junction capacitance C_{BL} of the PN junction between the drain N⁺ layer 103 to which the bit line is connected and the floating body 102, and is expressed as follows.

C_{FB}=C_{WL}+C_{BL}+C_{SL} (1)

Thus, a change in the word line voltage V_{WL} at the time of writing affects the voltage of the floating body 102 serving as the storage node (contact point) of the memory cell. This state is illustrated in FIG. 12B. At the time of writing, an increase in the word line voltage V_{WL} from 0 V to V_{ProgWL} results in an increase in the voltage V_{FB} of the floating body 102 from the initial voltage V_{FB1} of the original word line voltage to V_{FB2} due to capacitive coupling with the word line. The voltage change amount ΔV_{FB} is expressed as follows:

$$\begin{matrix}Δ {V}_{F B} = {V}_{F B 2} - {V}_{F B 1} \\ = {C}_{W L} / ( {C}_{W L} + {C}_{BL} + {C}_{S L} ) \times {C}_{Prog WL}\end{matrix} \qquad ( 2 )$$

where

β=C_{WL}/(C_{WL}+C_{BL}+C_{SL}) (3)

is expressed and β is referred to as a coupling ratio. In such a memory cell, C_{WL} has a high contribution ratio and, for example, C_{WL}:C_{BL}:C_{SL}=8:1:1. In this case, 13=0.8. When the word line changes, for example, from 5 V at the time of writing to 0 V at the end of writing, the capacitive coupling between the word line and the floating body 102 causes an amplitude noise as much as 5 V×β=4 V on the floating body 102. Thus, the potential difference margin is not sufficiently provided between the “1” potential and the “0” potential of the floating body at the time of writing, which is a problem.

FIGS. 13A and 13B illustrate the read operation. FIG. 13A illustrates the “1” write state, and FIG. 13B illustrates the “0” write state. However, actually, even when “1” is written to write Vb in the floating body 102, returning of the word line to 0 V upon completion of writing brings the floating body 102 to a negative bias. When “0” is written, lowering to a further negative bias is caused, so that, at the time of writing, the potential difference margin between “1” and “0” cannot be made sufficiently large. This small operation margin is a major problem of the DRAM memory cell. In addition, the DRAM memory cell needs to have a higher density.

There is a Twin-Transistor memory element in which, in an SOI (Silicon on Insulator) layer, two MOS transistors are used to form a single memory cell (refer to, for example, US2008/0137394A1 and US2003/0111681A1). In such an element, an N⁺ layer separating the floating body channels of the two MOS transistors and serving as the source or the drain is formed in contact with an insulating layer. This N⁺ layer is in contact with the insulating layer to thereby provide electric isolation between the floating body channels of the two MOS transistors. The hole group serving as signal charges is stored in the floating body channel of one of the transistors. As described above, the voltage of the floating body channel in which holes are stored considerably varies due to application of a pulse voltage to the gate electrode of the adjacent MOS transistor, as expressed in Formula (2). Thus, as has been described with reference to FIG. 11A to FIG. 13C, the operation margin between “1” and “0” at the time of writing cannot be made sufficiently large (refer to, for example, F. Morishita, H. Noda, I. Hayashi, T. Gyohten, M. Oksmoto, T. Ipposhi, S. Maegawa, K. Dosaka, and K. Arimoto: “Capacitorless Twin-Transistor Random Access Memory (TTRAM) on SOI”, IEICE Trans. Electron., Vol. E90-c., No. 4 pp. 765-771 (2007), and FIG. 8).

There are also other related art documents that are Japanese Unexamined Patent Application Publication No. 3-171768; Japanese Patent No. 3957774; J. Y. Song, W. Y. Choi, J. H. Park, J. D. Lee, and B-G. Park: “Design Optimization of Gate-All-Around (GAA) MOSFETs”, IEEE Trans. Electron Devices, vol. 5, no. 3, pp. 186-191, May 2006; N. Loubet, et al.: “Stacked Nanosheet Gate-All-Around Transistor to Enable Scaling Beyond FinFET”, 2017 IEEE Symposium on VLSI Technology Digest of Technical Papers, T17-5, T230-T231, June 2017; and H. Jiang, N. Xu, B. Chen, L. Zengl, Y. He, G. Du, X. Liu and X. Zhang: “Experimental investigation of self heating effect (SHE) in multiple-fin SOI FinFETs”, Semicond. Sci. Technol. 29 (2014) 115021 (7 pp).

### SUMMARY OF THE INVENTION

In a single-transistor DRAM (gain cell), capacitive coupling between the word line and the floating-state SGT body is strong; at the time of reading or writing of data, a change in the potential of the word line is transmitted directly as noise to the SGT body, which has been problematic. This causes problems of erroneous reading or erroneous writing of storage data and makes it difficult to put the capacitor-less single-transistor DRAM (gain cell) into practical use. The above-described problems need to be addressed and the DRAM memory cell needs to have a higher density. The memory cell and the fin transistor of the logic circuit need to be formed on the same substrate at low costs.

In order to address the above-described problems, the present invention provides a semiconductor memory device including:
a dynamic flash memory cell; and
a fin transistor,
wherein the dynamic flash memory cell includes
a first insulating layer on a semiconductor substrate,
a first fin semiconductor layer disposed on the first insulating layer and extending in a horizontal direction relative to the semiconductor substrate,
a first impurity region and a second impurity region that connect to both longitudinal sides of the first fin semiconductor layer,
a first gate insulating layer covering the first fin semiconductor layer,
a first gate conductor layer covering a portion of the first gate insulating layer, and
a second gate conductor layer that is adjacent to the first gate conductor layer and covers the first gate insulating layer,
the fin transistor includes
a second fin semiconductor layer that stands in a perpendicular direction relative to the semiconductor substrate and includes a bottom portion within the semiconductor substrate,
a third impurity region and a fourth impurity region that connect to both upper longitudinal sides of the second fin semiconductor layer,
a second gate insulating layer covering an upper surface and both side surfaces of an upper portion of the second fin semiconductor layer, and
a third gate conductor layer covering the second gate insulating layer,
in the perpendicular direction relative to the semiconductor substrate, a top portion of the first fin semiconductor layer is positioned close to a top portion of the second fin semiconductor layer,
in the perpendicular direction relative to the semiconductor substrate, bottom portions of the first gate insulating layer and the second gate insulating layer are positioned close to each other, and
in the perpendicular direction relative to the semiconductor substrate, the bottom portion of the second fin semiconductor layer is positioned within the semiconductor substrate (first invention).

In the first invention, the second fin semiconductor layer includes a lower portion being a portion of the semiconductor substrate and an upper portion being a first semiconductor layer (second invention).

In the first invention, the first gate insulating layer and the second gate insulating layer are layers formed of the same material (third invention).

In the first invention, the third gate conductor layer is a layer formed of the same material as in one or both of the first gate conductor layer and the second gate conductor layer (fourth invention).

In the first invention, in the perpendicular direction relative to the semiconductor substrate, an upper surface of the first fin semiconductor layer surrounded by the first gate conductor layer is positioned above an upper surface of the first fin semiconductor layer surrounded by the second gate conductor layer (fifth invention).

In the fifth invention, in the perpendicular direction relative to the semiconductor substrate, an upper surface of the second gate conductor layer is positioned below a bottom surface of the first gate conductor layer (sixth invention).

In the first invention, the first gate conductor layer includes a fourth gate conductor layer and a fifth gate conductor layer that are separated from each other and disposed on both side surfaces of the first fin semiconductor layer (seventh invention).

In the seventh invention, the third gate conductor layer includes a fifth gate conductor layer and a sixth gate conductor layer that are separated from each other and disposed on both side surfaces of the second fin semiconductor layer (eighth invention).

In the seventh invention, in the perpendicular direction relative to the semiconductor substrate, an upper surface of the first fin semiconductor layer is positioned higher than an upper surface of the second fin semiconductor layer and an upper surface of the third gate conductor layer is positioned close to the upper surface of the first fin semiconductor layer (ninth invention).

In the first invention, the first insulating layer has, in plan view, the same shape as the first fin semiconductor layer, and the semiconductor substrate connects to a bottom of the first insulating layer and includes an upper portion having, in plan view, substantially the same shape as the first fin semiconductor layer (tenth invention).

In the first invention, the semiconductor memory device further includes a second insulating layer surrounding a bottom portion of the first fin semiconductor layer, disposed over the first insulating layer, and disposed under the first gate insulating layer and the second gate insulating layer (eleventh invention).

In the first invention, a wiring line connecting to the first impurity region is a source line, a wiring line connecting to the second impurity region is a bit line, a wiring line connecting to the first gate conductor layer is a plate line, and a wiring line connecting to the second gate conductor layer is a word line, and one of the first gate conductor layer and the second gate conductor layer connects to the word line and another one of the first gate conductor layer and the second gate conductor layer connects to the plate line (twelfth invention).

In the first invention, a first gate capacitance between the first gate conductor layer and the first fin semiconductor layer is higher than a second gate capacitance between the second gate conductor layer and the first fin semiconductor layer (thirteenth invention).

In the first invention, the first impurity region and the second impurity region are N-type semiconductor layers containing a donor impurity at high concentration, and the first fin semiconductor layer is a P-type semiconductor layer containing an acceptor impurity (fourteenth invention).

In the first invention, the semiconductor memory device is configured to control voltages applied to the first impurity region, the second impurity region, the first gate conductor layer, and the second gate conductor layer to perform an operation of using a current flowing between the first impurity region and the second impurity region to cause an impact ionization phenomenon or using a gate induced drain leakage current, to generate an electron group and a hole group in the first fin semiconductor layer, an operation of discharging, of the generated electron group and hole group, the electron group or hole group serving as a minority carrier from the first impurity region or the second impurity region, and an operation of causing a portion or entirety of the hole group or electron group serving as a majority carrier to remain within the first fin semiconductor layer, to perform a memory write operation, and
the semiconductor memory device is configured to control voltages applied to the first impurity region, the second impurity region, the first gate conductor layer, and the second gate conductor layer to perform an operation of removing, from one or both of the first impurity region and the second impurity region, of the hole group and electron group, a remaining hole group or a remaining electron group, to perform a memory erase operation (fifteenth invention).

In the first invention, one or both of the first gate conductor layer and the second gate conductor layer are divided into two or more layers and the two or more layers are driven synchronously or asynchronously (sixteenth invention).

### BRIEF DESCRIPTION OF THE DRAWINGS

FIGS. 1A, 1B, and 1C are structural views of a memory cell in a memory device according to a first embodiment.

FIGS. 2A, 2B, and 2C are explanatory views of the erase operation mechanism of a memory cell in a memory device according to a first embodiment.

FIGS. 3A, 3B, and 3C are explanatory views of the write operation mechanism of a memory cell in a memory device according to a first embodiment.

FIGS. 4AA, 4AB, and 4AC are explanatory views of the read operation mechanism of a memory cell in a memory device according to a first embodiment.

FIGS. 4BA, 4BB, and 4BC are explanatory views of the read operation mechanism of a memory cell in a memory device according to a first embodiment.

FIG. 5A is an explanatory view of a method for producing a memory device according to a first embodiment in which a memory cell and a fin transistor of a logic circuit are formed on the same substrate.

FIG. 5B is an explanatory view of a method for producing a memory device according to a first embodiment in which a memory cell and a fin transistor of a logic circuit are formed on the same substrate.

FIG. 5C is an explanatory view of a method for producing a memory device according to a first embodiment in which a memory cell and a fin transistor of a logic circuit are formed on the same substrate.

FIG. 5D is an explanatory view of a method for producing a memory device according to a first embodiment in which a memory cell and a fin transistor of a logic circuit are formed on the same substrate.

FIG. 5E is an explanatory view of a method for producing a memory device according to a first embodiment in which a memory cell and a fin transistor of a logic circuit are formed on the same substrate.

FIG. 5F is an explanatory view of a method for producing a memory device according to a first embodiment in which a memory cell and a fin transistor of a logic circuit are formed on the same substrate.

FIG. 5G is an explanatory view of a method for producing a memory device according to a first embodiment in which a memory cell and a fin transistor of a logic circuit are formed on the same substrate.

FIG. 5H is an explanatory view of a method for producing a memory device according to a first embodiment in which a memory cell and a fin transistor of a logic circuit are formed on the same substrate.

FIG. 5I is an explanatory view of a method for producing a memory device according to a first embodiment in which a memory cell and a fin transistor of a logic circuit are formed on the same substrate.

FIG. 5J is an explanatory view of a method for producing a memory device according to a first embodiment in which a memory cell and a fin transistor of a logic circuit are formed on the same substrate.

FIGS. 5KA and 5KB are explanatory views of a method for producing a memory device according to a first embodiment in which a memory cell and a fin transistor of a logic circuit are formed on the same substrate.

FIGS. 5LA and 5LB are explanatory views of a method for producing a memory device according to a first embodiment in which a memory cell and a fin transistor of a logic circuit are formed on the same substrate.

FIGS. 5MA and 5MB are explanatory views of a method for producing a memory device according to a first embodiment in which a memory cell and a fin transistor of a logic circuit are formed on the same substrate.

FIGS. 6A and 6B are explanatory views of, in a memory device according to a second embodiment, a memory cell and a fin transistor of a logic circuit that are formed on the same substrate.

FIGS. 7A, 7B, and 7C are explanatory views of, in a memory device according to a third embodiment, a memory cell and a fin transistor of a logic circuit that are formed on the same substrate.

FIG. 8 is an explanatory view of, in a memory device according to a fourth embodiment, a memory cell and a fin transistor of a logic circuit that are formed on the same substrate.

FIGS. 9A and 9B are explanatory views of, in a memory device according to a fifth embodiment, a memory cell and a fin transistor of a logic circuit that are formed on the same substrate.

FIG. 10 is an explanatory view of, in a memory device according to a fifth embodiment, a memory cell and a fin transistor of a logic circuit that are formed on the same substrate.

FIGS. 11A, 11B, 11C, and 11D are explanatory views of a problem in the operation of a related-art capacitor-less DRAM memory cell.

FIGS. 12A and 12B are explanatory views of a problem in the operation of a related-art capacitor-less DRAM memory cell.

FIGS. 13A, 13B, and 13C illustrate the read operation of a related-art capacitor-less DRAM memory cell.

### DESCRIPTION OF THE PREFERRED EMBODIMENTS

Hereinafter, in memory (hereafter, referred to as a dynamic flash memory) devices according to embodiments of the present invention, memory cells and fin transistors of logic circuits will be described with reference to the drawings.

### First Embodiment

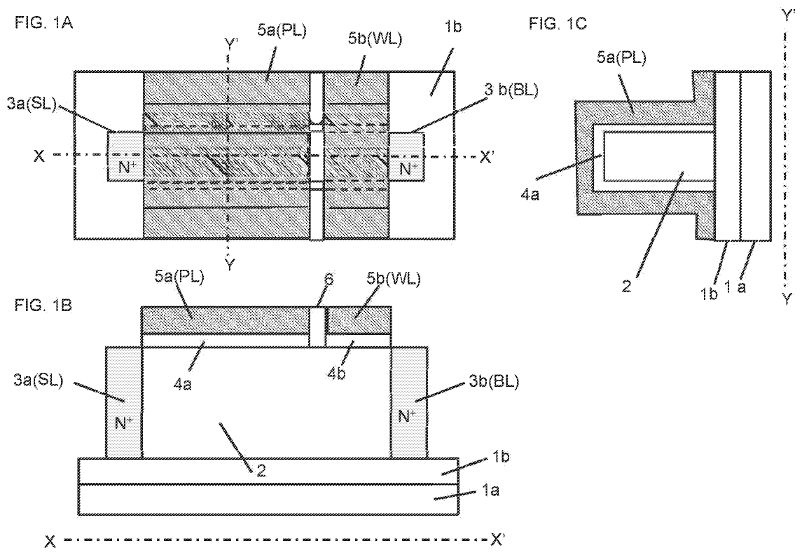

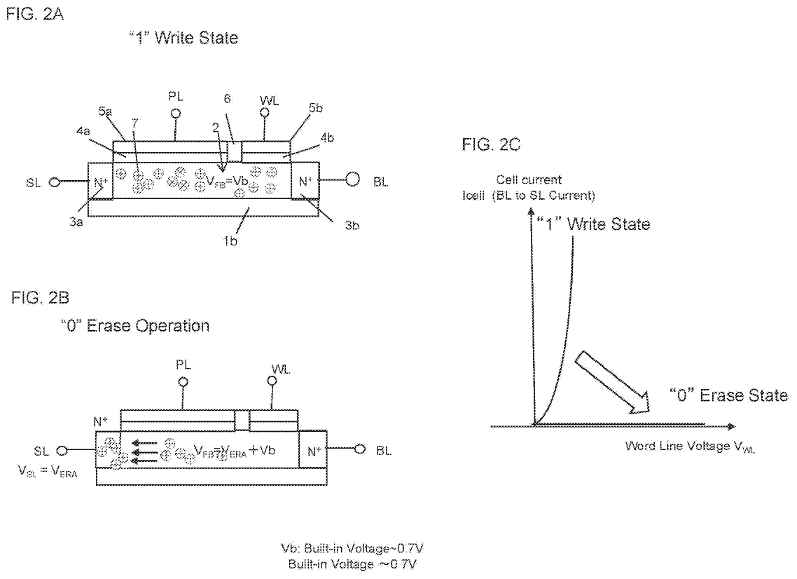

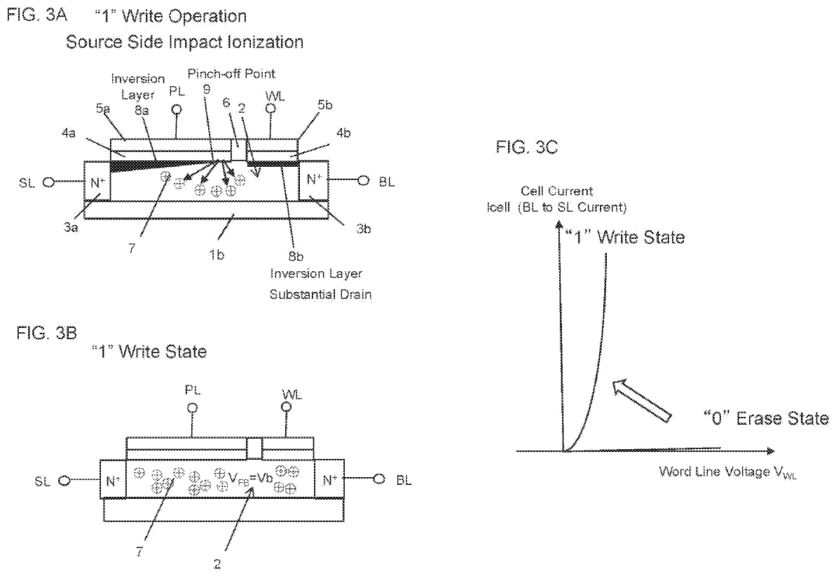

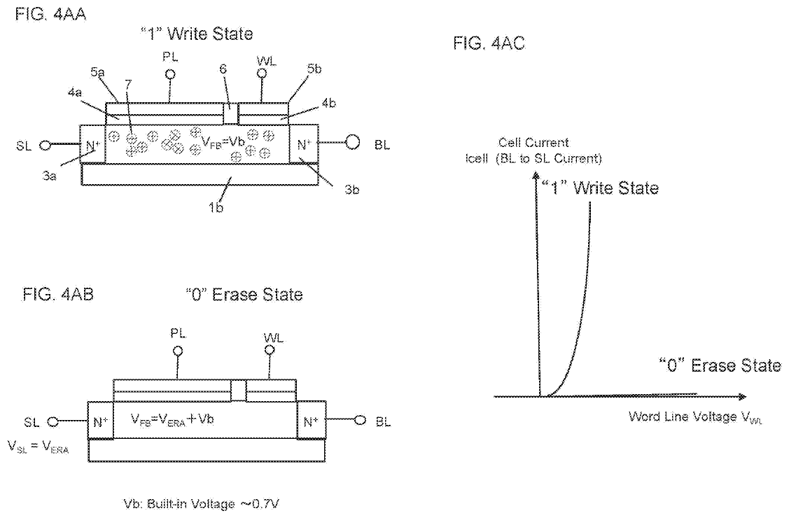

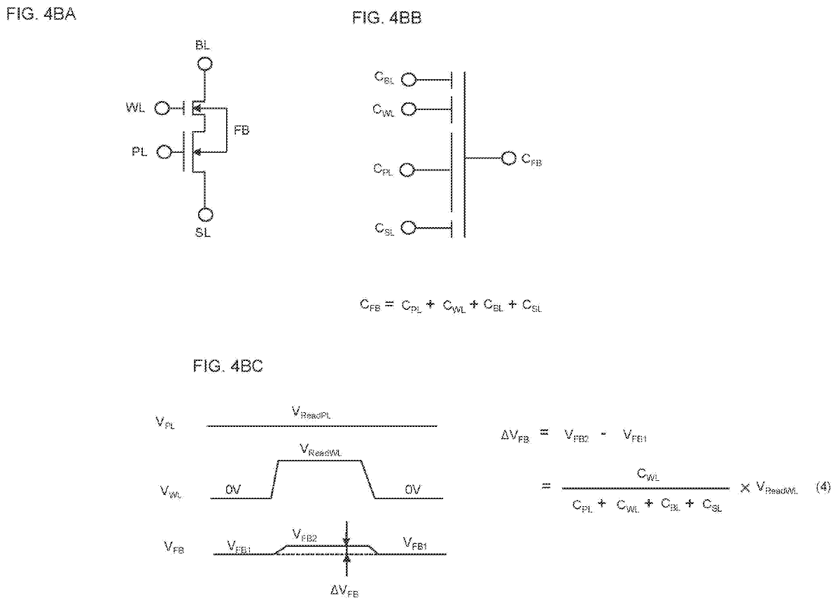

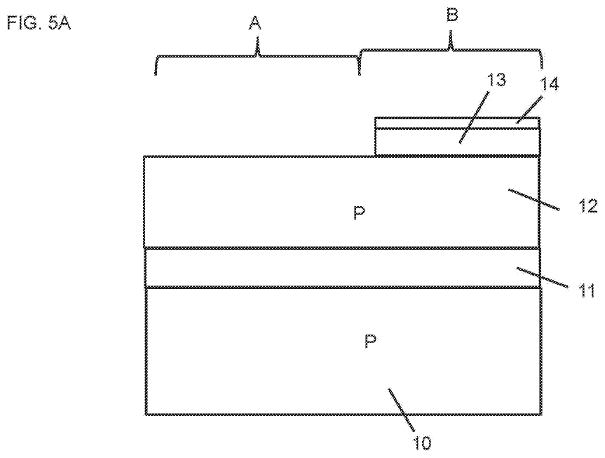

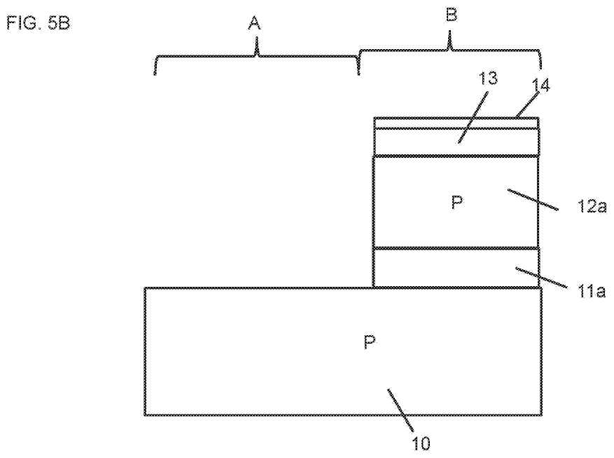

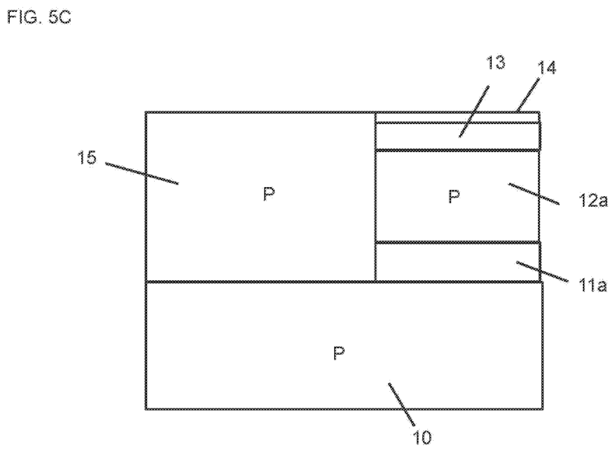

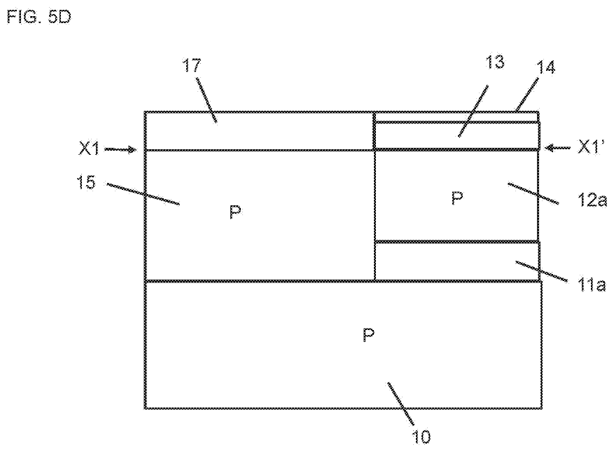

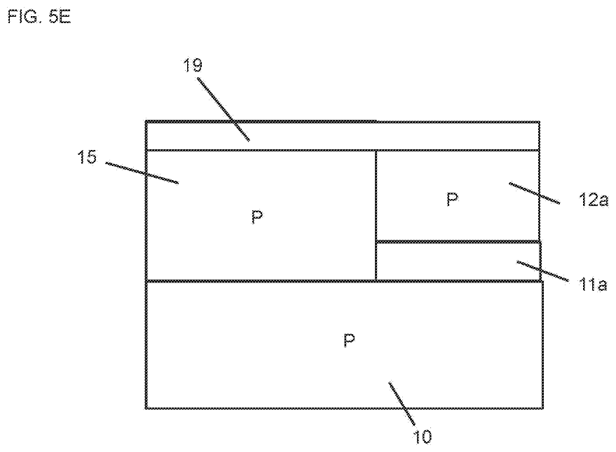

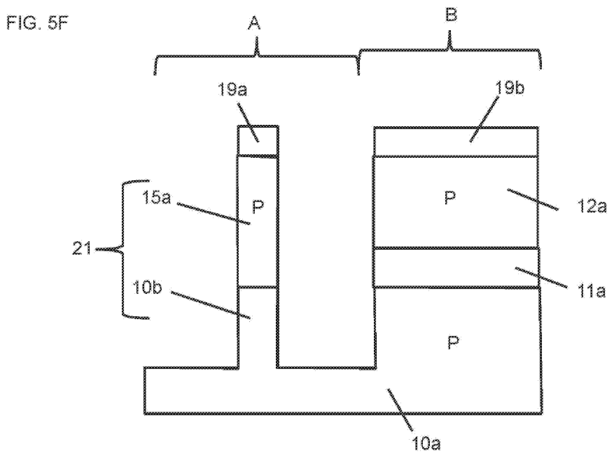

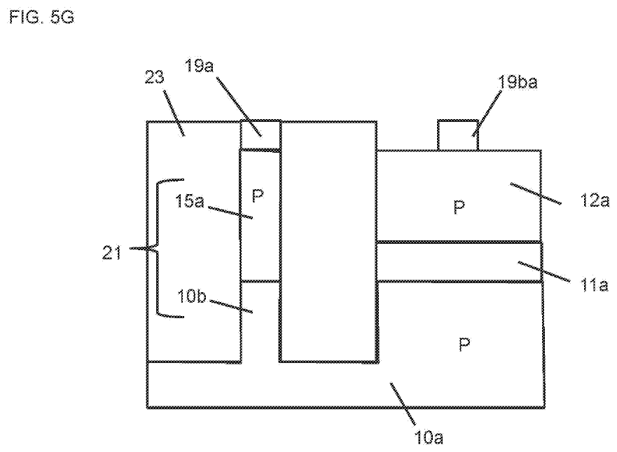

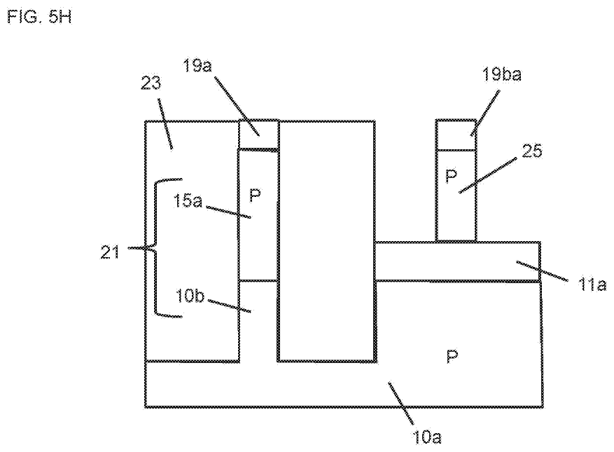

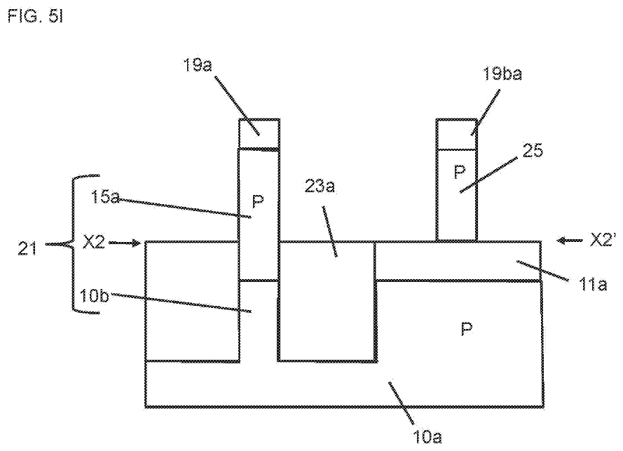

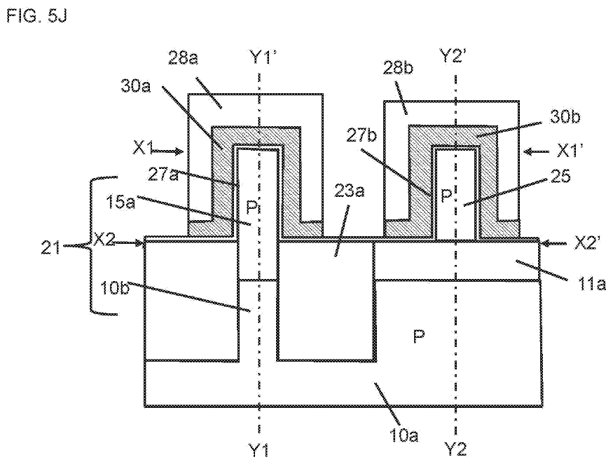

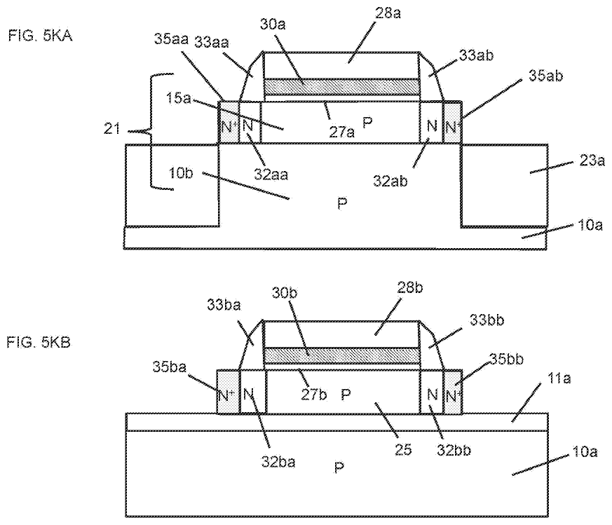

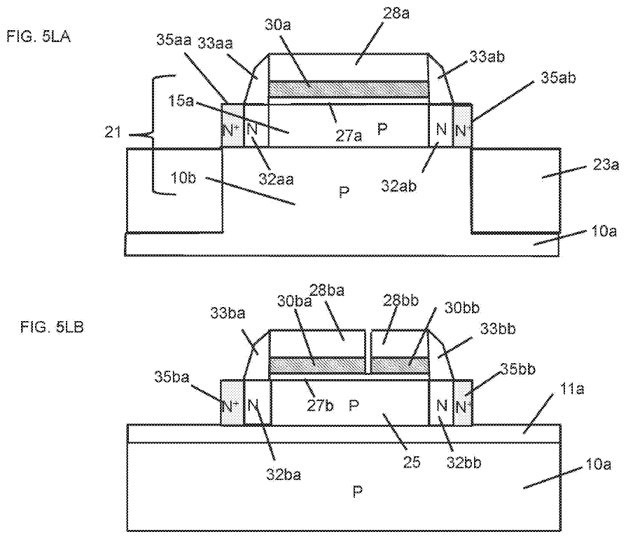

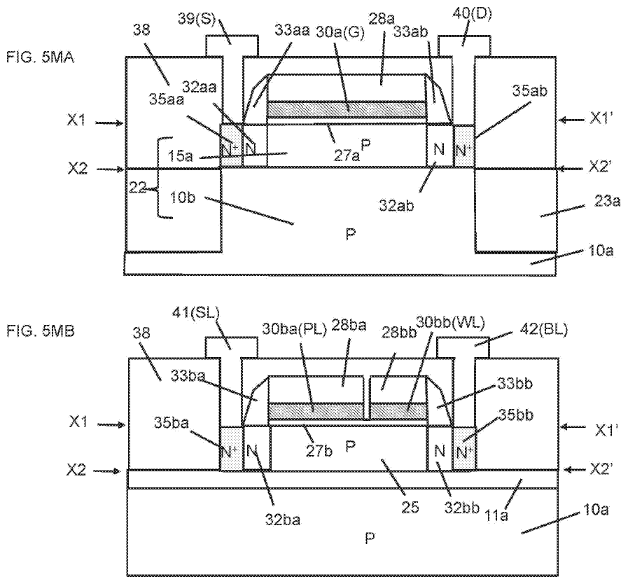

FIG. 1A to FIG. 5MB will be used to describe a dynamic flash memory cell according to a first embodiment of the present invention in terms of structure, operation mechanisms, and production method. FIGS. 1A to 1C will be used to describe the structure of the dynamic flash memory cell. Subsequently, FIGS. 2A to 2C will be used to describe the data erase mechanism; FIGS. 3A to 3C will be used to describe the data write mechanism; FIGS. 4AA to 4BC will be used to describe the data write mechanism. FIGS. 5A to 5MB will be used to describe the production method for forming a memory cell and a fin transistor of a logic circuit region.

FIGS. 1A to 1C illustrate the structures of a dynamic flash memory cell according to the first embodiment of the present invention. FIG. 1A is a plan view. FIG. 1B is a vertical sectional view taken along line X-X′ in FIG. 1A. FIG. 1C is a vertical sectional view taken along line Y-Y′ in FIG. 1A. On a semiconductor substrate 1a (serving as an example of “semiconductor substrate” in Claims) and an insulating layer 1b (serving as an example of “first insulating layer” in Claims), a fin-shaped first fin semiconductor layer 2 having a conductivity type of a P-type or an i-type (intrinsic type) (serving as an example of “first fin semiconductor layer” in Claims) is formed. On both sides (in X-X′ direction) of the first fin semiconductor layer 2, an N⁺ layer 3a (serving as an example of “first impurity region” in Claims) and an N⁺ layer 3b (serving as an example of “second impurity region” in Claims), one of which serves as a source and the other one of which serves as a drain, are formed. The region of the first fin semiconductor layer 2 between the N⁺ layers 3a and 3b serving as the source and the drain serves as the channel region. First gate insulating layers 4a and 4b (serving as an example of “first gate insulating layer” in Claims) are formed so as to surround the first fin semiconductor layer 2. The first gate insulating layers 4a and 4b are respectively disposed in contact with or close to the N⁺ layers 3a and 3b serving as the source and the drain. A first gate conductor layer 5a (serving as an example of “first gate conductor layer” in Claims) and a second gate conductor layer 5b (serving as an example of “second gate conductor layer” in Claims) are respectively formed so as to surround the first gate insulating layers 4a and 4b. The first gate conductor layer 5a and the second gate conductor layer 5b are isolated from each other by an insulating layer 6. Thus, the N⁺ layers 3a and 3b serving as the source and the drain, the first fin semiconductor layer 2, the first gate insulating layers 4a and 4b, the first gate conductor layer 5a, and the second gate conductor layer 5b constitute a dynamic flash memory cell. The N⁺ layer 3a serving as the source connects to a source line SL (serving as an example of “source line” in Claims). The N⁺ layer 3b serving as the drain connects to a bit line BL (serving as an example of “bit line” in Claims). The first gate conductor layer 5a connects to a plate line PL (serving as an example of “plate line” in Claims). The second gate conductor layer 5b connects to a word line WL (serving as an example of “word line” in Claims). Note that the structure is designed such that the first gate conductor layer 5a to which the plate line PL is connected has a gate capacitance higher than the gate capacitance of the second gate conductor layer 5b to which the word line WL is connected. Note that, in FIG. 1B, the insulating layer 6 is disposed between the first gate insulating layers 4a and 4b; alternatively, the first gate insulating layers 4a and 4b may be continuously formed.

Referring to FIGS. 2A to 2C, the erase operation mechanism will be described. FIGS. 2A and 2B schematically illustrate the sectional view of FIG. 1B. The first fin semiconductor layer 2 between the N⁺ layers 3a and 3b is electrically isolated from the substrate and serves as a floating body. FIG. 2A illustrates a state in which, before the erase operation, hole groups 7 generated in the previous cycle by impact ionization are stored in the first fin semiconductor layer 2. As illustrated in FIG. 2B, during the erase operation, the voltage of the bit line BL is set to a negative voltage V_{ERA}. V_{ERA} is, for example, −3 V. As a result, irrespective of the initial potential of the first fin semiconductor layer 2, the PN junction between the first fin semiconductor layer 2 and the N⁺ layer 3a to which the source line SL is connected and which serves as the source is forward-biased. As a result, the hole groups 7 generated in the previous cycle by impact ionization and stored in the first fin semiconductor layer 2 are drawn into the N⁺ layer 3a serving as the source region and the potential V_{FB} of the first fin semiconductor layer 2 becomes V_{FB}=V_{ERA}+Vb, where Vb is the built-in voltage of the PN junction and is about 0.7 V. Thus, when V_{ERA}=−3 V, the potential of the first fin semiconductor layer 2 becomes −2.3 V. This value represents the potential state of the first fin semiconductor layer 2 in the erase state. Thus, when the potential of the first fin semiconductor layer 2 being a floating body becomes a negative voltage, the threshold voltage of the N channel MOS transistor increases due to the substrate-bias effect. As a result, as illustrated in FIG. 2C, the second gate conductor layer 5b to which the word line WL is connected has an increased threshold voltage. This erase state of the first fin semiconductor layer 2 is assigned to logical storage data “0”. Note that the above-described conditions of voltages applied to the bit line BL, the source line SL, the word line WL, and the plate line PL are an example for performing the erase operation, and other voltage conditions under which the erase operation can be performed may be employed.

Referring to FIGS. 3A to 3C, the write operation of the dynamic flash memory cell according to the first embodiment of the present invention will be described. FIGS. 3A and 3B correspond to the sectional view of FIG. 1B. As illustrated in FIG. 3A, for example, 0 V is applied to the N⁺ layer 3a to which the source line SL is connected; for example, 3 V is applied to the N⁺ layer 3b to which the bit line BL is connected; for example, 2 V is applied to the first gate conductor layer 5a to which the plate line PL is connected; for example, 5 V is applied to the second gate conductor layer 5b to which the word line WL is connected. As a result, as illustrated in FIG. 3A, in the first fin semiconductor layer 2 positioned inside relative to the first gate conductor layer 5a to which the plate line PL is connected, an inversion layer 8a is formed and the first N channel MOS transistor region including the first gate conductor layer 5a operates in the saturation region. As a result, in the inversion layer 8a positioned inside relative to the first gate conductor layer 5a to which the plate line PL is connected, a pinch-off point 9 is present. On the other hand, the second N channel MOS transistor region including the second gate conductor layer 5b to which the word line WL is connected is operated in the linear region. As a result, in the first fin semiconductor layer 2 positioned inside relative to the second gate conductor layer 5b to which the word line WL is connected, the pinch-off point is not present and an inversion layer 8b is formed over the entire surface positioned inside relative to the gate conductor layer 5b. This inversion layer 8b formed over the entire surface positioned inside relative to the second gate conductor layer 5b to which the word line WL is connected serves substantially as the drain of the second N channel MOS transistor region including the second gate conductor layer 5b. As a result, the electric field becomes maximum in the boundary region of the first fin semiconductor layer 2 between the first N channel MOS transistor region including the first gate conductor layer 5a and the second N channel MOS transistor region including the second gate conductor layer 5b that are connected in series and, in this boundary region, an impact ionization phenomenon is caused. This region is a source-side region when viewed from the second N channel MOS transistor region including the second gate conductor layer 5b to which the word line WL is connected and hence this phenomenon will be referred to as a source-side impact ionization phenomenon. This source-side impact ionization phenomenon causes electrons to flow from the N⁺ layer 3a to which the source line SL is connected toward the N⁺ layer 3b to which the bit line is connected. Accelerated electrons collide with lattice Si atoms, and the kinetic energy causes generation of electron-hole pairs. A portion of the generated electrons flow to the first gate conductor layer 5a and the second gate conductor layer 5b, but most of the generated electrons flow to the N⁺ layer 3b to which the bit line BL is connected. In writing of “1”, GIDL (Gate Induced Drain Leakage) current may be used to generate electron-hole pairs to cause the generated hole group to fill the floating body FB (refer to E. Yoshida, and T. Tanaka: “A Capacitorless 1T-DRAM Technology Using Gate-Induced Drain-Leakage (GIDL) Current for Low-Power and High-Speed Embedded Memory”, IEEE Transactions on Electron Devices, Vol. 53, No. 4, pp. 692-697, April 2006).

As illustrated in FIG. 3B, the generated hole group 7 is the majority carrier of the first fin semiconductor layer 2 and charges the first fin semiconductor layer 2 to a positive bias. The N⁺ layer 3a to which the source line SL is connected is at 0 V, and hence the first fin semiconductor layer 2 is charged to the built-in voltage Vb (about 0.7 V) of the PN junction between the N⁺ layer 3a to which the source line SL is connected and the first fin semiconductor layer 2. When the first fin semiconductor layer 2 is charged to a positive bias, the threshold voltages of the first N channel MOS transistor region and the second N channel MOS transistor region decrease due to the substrate-bias effect. This results in, as illustrated in FIG. 3C, a decrease in the threshold voltage of the first fin semiconductor layer 2 of the second N channel MOS transistor to which the word line WL is connected. This write state of the first fin semiconductor layer 2 is assigned to logical storage data “1”.

Note that, at the time of the write operation, in the boundary region between the N⁺ layer 3a and the first fin semiconductor layer 2 or in the boundary region between the N⁺ layer 3b and the first fin semiconductor layer 2, an impact ionization phenomenon or a GIDL current may be caused to generate electron-hole pairs and the hole groups 7 generated may be used to charge the first fin semiconductor layer 2. Note that the above-described conditions of voltages applied to the bit line BL, the source line SL, the word line WL, and the plate line PL are an example for performing the write operation; other operation conditions under which the write operation can be performed may be employed. The impact ionization phenomenon may be caused in a portion or the entirety of the second N channel MOS transistor region.

Referring to FIGS. 4AA to 4BC, the dynamic flash memory cell according to the first embodiment of the present invention will be described in terms of read operation and its related memory cell structure. Referring to FIGS. 4AA to 4AC, the read operation of the dynamic flash memory cell will be described. FIGS. 4AA and 4AB correspond to the sectional view of FIG. 1B. As illustrated in FIG. 4AA, when the first fin semiconductor layer 2 is charged to the built-in voltage Vb (about 0.7 V), the threshold voltage of the N channel MOS transistor decreases due to the substrate-bias effect. As described above, this state is assigned to logical storage data “1”. As illustrated in FIG. 4AB, when the memory block selected prior to writing is in an erase state “0” in advance, the first fin semiconductor layer 2 is at a floating voltage V_{FB} equal to V_{ERA}+Vb. The write operation causes random storage of write state “1”. This results in, for the word line WL, generation of logical storage data of logical “0” and “1”. As illustrated in FIG. 4AC, the difference between the two threshold voltages for the word line WL is used to perform reading using a sense amplifier.

Referring to FIGS. 4BA to 4BC, for the dynamic flash memory cell according to the first embodiment of the present invention, at the time of the read operation, the first gate conductor layer 5a and the second gate conductor layer 5b will be described in terms of the magnitude relation of the two gate capacitances and their related operations. The gate capacitance of the second gate conductor layer 5b to which the word line WL connects is desirably designed so as to be lower than the gate capacitance of the first gate conductor layer 5a to which the plate line PL connects. Thus, as illustrated in FIG. 4BA, the horizontal length of the first gate conductor layer 5a to which the plate line PL connects is set to be larger than the horizontal length of the second gate conductor layer 5b to which the word line WL connects, and the gate capacitance of the second gate conductor layer 5b to which the word line WL connects is set to be lower than the gate capacitance of the first gate conductor layer 5a to which the plate line PL connects. FIG. 4BB illustrates the equivalent circuit of the single cell of the dynamic flash memory in FIG. 4BA. FIG. 4BC illustrates the coupling capacitance relation of the dynamic flash memory where C_{WL} is the capacitance of the second gate conductor layer 5b, C_{PL} is the capacitance of the first gate conductor layer 5a, C_{BL} is the capacitance of the PN junction between the N⁺ layer 3b serving as the drain and the first fin semiconductor layer 2, and C_{SL} is the capacitance of the PN junction between the N⁺ layer 3a serving as the source and the first fin semiconductor layer 2. As illustrated in FIG. 4BC, when the voltage of the word line WL changes, its operation affects, as noise, the first fin semiconductor layer 2. At this time, the potential change ΔV_{FB} of the first fin semiconductor layer 2 is expressed as follows.

ΔV_{FB}=V_{FB2}−V_{FB1}=C_{WL}/(C_{PL}+C_{WL}+C_{BL}+C_{SL})×V_{ReadWL} (4)

where V_{ReadWL} is the changing potential of the word line WL at the time of reading. As is clear from Formula (4), relative to the total capacitance C_{PL}+C_{WL}+C_{BL}+C_{SL} of the first fin semiconductor layer 2, a decrease in the contribution ratio of C_{WL} results in a decrease in ΔV_{FB}. Note that the above-described conditions of voltages applied to the bit line BL, the source line SL, the word line WL, and the plate line PL are an example for performing the read operation; other voltage conditions under which the read operation can be performed may be employed.

Note that one or both of the first gate conductor layer 5a and the second gate conductor layer 5b may be divided, in the extension direction of the first fin semiconductor layer 2, into two or more layers and the two or more layers may be driven synchronously or asynchronously. This also causes the dynamic flash memory to operate. In this case, the divided layers of each of the first gate conductor layer and the second gate conductor layer may have the same length or different lengths in the extension direction of the first fin semiconductor layer 2.

Referring to FIG. 5A to FIG. 5MB (hereafter, these drawings may also be collectively referred to as “FIG. 5”), the production method according to this embodiment in which a dynamic flash memory cell and a fin transistor are formed on the same substrate will be described. In the actual memory device, a large number of dynamic flash memory cells and a large number of fin transistors are formed on the same substrate.

As illustrated in FIG. 5A, on a P layer substrate 10 (serving as an example of “semiconductor substrate” in Claims), a silicon oxide (SiO₂) layer 11 (serving as an example of “first insulating layer” in Claims) and a P layer 12 are formed. Subsequently, on a region B in which a dynamic flash memory cell on the P layer 12 is to be formed, a first mask material layer 13 and a second mask material layer 14 are formed. In a region A in which a fin transistor is to be formed, the first mask material layer 13 and the second mask material layer 14 are not formed.

Subsequently, as illustrated in FIG. 5B, the first mask material layer 13 and the second mask material layer 14 formed of, for example, a silicon nitride (SiN) film are used as masks and the P layer 12 and the SiO₂ layer 11 are etched to form, under the first mask material layer 13 and the second mask material layer 14, a P layer 12a and a SiO₂ layer 11a.

Subsequently, as illustrated in FIG. 5C, a P-type Si layer (not shown) is formed by an epitaxial crystal growth process so as to have an upper surface positioned above the second mask material layer 14. Subsequently, the P-type Si layer is polished by a CMP (Chemical Mechanical Polishing) process such that the upper surface is lowered to the level of the upper surface of the second mask material layer 14 to form a P layer 15.

Subsequently, as illustrated in FIG. 5D, the surface layer of the P layer 15 is oxidized to form a SiO₂ layer 17. In this case, the oxidation is desirably performed such that the bottom portion of the SiO₂ layer 17 corresponds to the upper surface (line X1-X1′ in FIG. 5D) of the P layer 12a. In this case, the upper surface of the P layer 15 and the upper surface of the P layer 12a substantially coincide on line X1-X1′.

Subsequently, the first mask material layer 13, the second mask material layer 14, and the SiO₂ layer 17 are removed. Subsequently, as illustrated in FIG. 5E, an insulating layer 19 is formed over the entire surface. The insulating layer 19 is desirably constituted by a plurality of material layers including, for example, a SiO₂ layer and a SiN layer that are to serve as stoppers in CMP and RIE in later steps.

Subsequently, as illustrated in FIG. 5F, a lithographic process and an RIE (Reactive Ion Etching) process are performed, in the region A in which a fin transistor is to be formed, to form an insulating layer 19a having a rectangular shape in plan view (elongated in the direction perpendicular to the paper of the drawing) and an insulating layer 19b covering the region B in which a dynamic flash memory cell is to be formed. Subsequently, the insulating layers 19a and 19b are used as masks and the P layers 15 and 10a are etched to form, on the P layer 10a, a fin P layer 21 (serving as an example of “second fin semiconductor layer” in Claims). This fin P layer 21 is constituted by a fin P layer 10b being a portion of the P layer 10a and a fin P layer 15a being a portion of the P layer 15. The insulating layers 19a and 19b will be subjected to a plurality of CMP and RIE steps in later steps and hence are constituted by a plurality of stopper layers.

Subsequently, as illustrated in FIG. 5G, a CVD (Chemical Vapor Deposition) process is performed to deposit a SiO₂ layer (not shown) over the entire structure; the SiO₂ layer is polished by a CMP process such that the upper surface is lowered to the level of the upper surfaces of the insulating layers 19a and 19b to form a SiO₂ layer 23. The upper surface of the SiO₂ layer 23 corresponds to the upper surfaces of the insulating layers 19a and 19b. Subsequently, a lithographic process and an RIE process are performed to form an insulating layer 19ba having a rectangular shape in plan view (elongated in the direction perpendicular to the paper of the drawing).

Subsequently, as illustrated in FIG. 5H, the insulating layer 19ba is used as a mask and the P layer 12a is etched to form a fin P layer 25 (serving as an example of “first fin semiconductor layer” in Claims).

Subsequently, a CVD process and a CMP process are performed over the entire structure to form, in the outer peripheral region around the fin P layer 25 and the insulating layer 19ba, an insulating layer (not shown) so as to have an upper surface positioned so as to correspond to the upper surface of the insulating layer 19a. Subsequently, as illustrated in FIG. 5I, the entire structure is subjected to an RIE process to etch the SiO₂ layer 23 in the outer peripheral region around the fin P layer 21 and the insulating layer in the outer peripheral region around the fin P layer 25 such that the upper surfaces of the SiO₂ layer 23 and the insulating layer are lowered to the level of the upper surface of the SiO₂ layer 11a to form a SiO₂ layer 23a. The upper surface of the SiO₂ layer 23a is desirably positioned so as to correspond to the upper surface (line X2-X2′ in FIG. 5I) of the SiO₂ layer 11a. Thus, the upper surface of the SiO₂ layer 23a substantially corresponds to, on line X2-X2′, the upper surface of the SiO₂ layer 11a.

Subsequently, as illustrated in FIG. 5J, the insulating layers 19a and 19ba are removed. Subsequently, a gate insulating layer 27a (in this embodiment, serving as an example of “second gate insulating layer” in Claims) is formed so as to cover the outer peripheral portion of the fin P layer 15a and a gate insulating layer 27b (in this embodiment, serving as an example of “first gate insulating layer” in Claims) is formed so as to cover the outer peripheral portion of the fin P layer 25. Subsequently, a conductor layer (not shown) that is to serve as the gate is deposited over the entire structure. Subsequently, mask insulating layers 28a and 28b are used as masks and an RIE process is performed to etch the material layer that is to serve as the gate, to form gate conductor layers 30a (serving as an example of “third gate conductor layer” in Claims) and 30b.

Subsequently, a step illustrated in FIGS. 5KA and 5KB is performed. FIG. 5KA is a sectional view taken along line Y1-Y1′ in FIG. 5J. FIG. 5KB is a sectional view taken along line Y2-Y2′ in FIG. 5J. An ion implantation process is performed in regions (outside of the gate conductor layer 30a) of the fin P layer 15a to form N layers 32aa and 32ab. Similarly, an ion implantation process is performed in regions (outside of the gate conductor layer 30b) of the fin P layer 25 to form N layers 32ba and 32bb. Subsequently, on both side surfaces of the gate insulating layer 27a, the gate conductor layer 30a, and the mask insulating layer 28a, spacer material layers 33aa and 33ab are formed. Similarly, on both side surfaces of the gate insulating layer 27b, the gate conductor layer 30b, and the mask insulating layer 28b, spacer material layers 33ba and 33bb are formed. Subsequently, an ion implantation process is performed to implant a donor impurity at a high concentration to form, in regions (in plan view, outside of the spacer material layers 33aa and 33ab) of the fin P layer 15a, N⁺ layers 35aa (serving as an example of “third impurity region” in Claims) and 35ab (serving as an example of “fourth impurity region” in Claims). Similarly, in regions (outside of the spacer material layers 33ba and 33bb) of the fin P layer 25, N⁺ layers 35ba (serving as an example of “first impurity region” in Claims) and 35bb (serving as an example of “second impurity region” in Claims) are formed. Note that, in this structure, the N layer 32aa and the N⁺ layer 35aa may be collectively referred to as the “third impurity region”. Similarly, the N⁺ layers 35ab and the N layer 32ab may be collectively referred to as the “fourth impurity region”; the N layer 32ba and the N⁺ layer 35ba may be collectively referred to as the “first impurity region”; the N layer 32bb and the N⁺ layer 35bb may be collectively referred to as the “second impurity region”.

Subsequently, as illustrated in FIGS. 5LA and 5LB, a lithographic process and an RIE process are performed to etch the insulating layer 28b and the gate conductor layer 30b to form gate conductor layers 30ba (serving as an example of “first gate conductor layer” in Claims) and 30bb (serving as an example of “second gate conductor layer” in) that are separated from each other and mask insulating layers 28ba and 28bb that are separated from each other.

Subsequently, as illustrated in FIGS. 5MA and 5MB, a CVD process and a CMP process are performed over the entire structure to form a SiO₂ layer 38. A lithographic process and an RIE process are performed to form metal wiring layers 39, 40, 41, and 42 connecting to the N⁺ layers 35aa, 35ab, 35ba, and 35bb and extending over the SiO₂ layer 38. Similarly, metal wiring layers (not shown) connecting to the gate conductor layers 30a, 30ba, and 30bb are formed. The metal wiring layer 39 connects to the source line S of the fin transistor; the metal wiring layer 40 connects to the drain line D of the fin transistor; the gate conductor layer 30a connects to the gate line G of the fin transistor. The metal wiring layer 41 connects to the source line SL of the dynamic flash memory cell; the metal wiring layer 42 connects to the bit line BL of the dynamic flash memory cell; the gate conductor layer 30ba connects to the plate line PL; the gate conductor layer 30bb connects to the word line WL. Thus, on the P layer substrate 10a, the dynamic flash memory cell and the fin transistor of the logic circuit are formed.

Note that, for FIGS. 5A to 5MB, the logic circuit has been described in terms of formation of the N-channel fin transistor. However, on the same P layer substrate 10a, a P-channel fin transistor is similarly formed. In the logic circuit region, a well structure may be formed in the P layer substrate 10a.

In FIGS. 1A to 1C, the gate conductor layer 5a is constituted by a single conductor layer. By contrast, the gate conductor layer 5a in FIG. 1A may be constituted by, in plan view, two conductor layers divided into upper and lower portions. In this case, voltages applied to the two gate conductor layers can be changed, to thereby improve the operation characteristics. Alternatively, the gate conductor layer 5a in FIG. 1A may be constituted by at least two or more conductor layers disposed side by side in plan view and the conductor layers may be driven synchronously or asynchronously. The same applies to the gate conductor layer 5b. The same applies to the gate conductor layers 30ba and 30bb in FIGS. 5LB and 5MB.

In FIGS. 5KA to 5MB, the acceptor impurity concentrations of the P layer 10a and the fin P layers 15a and 25 may be different in accordance with the device design of the dynamic flash memory cell and the fin transistor. The layers may be formed as layers different in semiconductor material.

In FIG. 5LB, the gate conductor layers 30ba and 30bb, which are separated from each other, and the mask insulating layers 28ba and 28bb, which are separated from each other, may be formed by a lithographic process and an RIE process or by other processes. The gate conductor layers 30ba and 30bb, which are separated from each other, may be separately formed. In this case, the gate conductor layers 30ba and 30bb may be formed as layers that are different in conductor material.

Alternatively, the gate conductor layers 30ba and 30bb may be formed so as to be insulated from each other and overlap in a sectional view. In this case, the gate insulating layer material surrounded by the gate conductor layer 30ba and the gate conductor layer 30bb may be different.

In FIG. 5B, in the region A in which the fin transistor is to be formed, the upper surface of the P layer 10a is positioned so as to correspond to the bottom portion of the SiO₂ layer 11a in the region B in which the dynamic flash memory cell is to be formed; alternatively, the upper surface of the P layer 10a may not correspond to the bottom portion of the SiO₂ layer 11a. In this case, in the fin P layer 21 illustrated in FIG. 5F, the perpendicular lengths of the P layer 10b and the fin P layer 15a can be changed.

Alternatively, unless the first mask material layer 13, the second mask material layer 14, the SiO₂ layers 11, 17, and 23, the insulating layer 19, the gate insulating layers 27a and 27b, the gate conductor layers 30a and 30b, the mask insulating layers 28a and 28b, and the like hamper the purposes of the steps, the layers may be formed of other materials or may each be formed as a plurality of material layers.

This embodiment has the following features.

### Feature 1

When the dynamic flash memory cell according to this embodiment in FIGS. 1A to 1C performs the write or read operation, the voltage of the word line WL changes up and down. At this time, the plate line PL plays the role of reducing the capacitive coupling ratio between the word line WL and the semiconductor layer 2. As a result, during up-and-down changes in the voltage of the word line WL, the effect due to the changes in the voltage in the P layer 2 can be considerably suppressed. As a result, the difference between the threshold voltages of the MOS transistor region for the word line WL indicating logic “0” and “1” can be made to be large. This leads to an increase in the operation margin of the dynamic flash memory cell.

### Feature 2

As illustrated in FIG. 5I, on the SiO₂ layers 23a and 11a having upper surfaces positioned substantially at the same level, the fin P layer 25 serving as the channel of the dynamic flash memory cell and the fin P layer 15a serving as the channel of the fin transistor of the logic circuit are formed. In subsequent steps, except for the separation step for the gate conductor layers 30ba and 30bb and the mask insulating layers 28ba and 28bb of the dynamic flash memory cell in FIG. 5LB, the basic steps for the dynamic flash memory cell and the fin transistor of the logic circuit are the same. This simplifies the method for producing the dynamic flash memory device. This leads to a reduction in the costs of the dynamic flash memory device.

### Feature 3

In the above-described production of the dynamic flash memory device, the fin P layer 21 of the fin transistor and the fin P layer 25 of the dynamic flash memory cell are formed so as to have top portions positioned at the same level in the perpendicular direction, to thereby simplify the step of FIG. 5H and subsequent steps. Below the level (serving as a reference) of the top portion of the fin P layer 25 in the perpendicular direction, as illustrated in FIG. 5F, the perpendicular length of the fin P layer 21 can be set in accordance with the design requirements.

### Second Embodiment

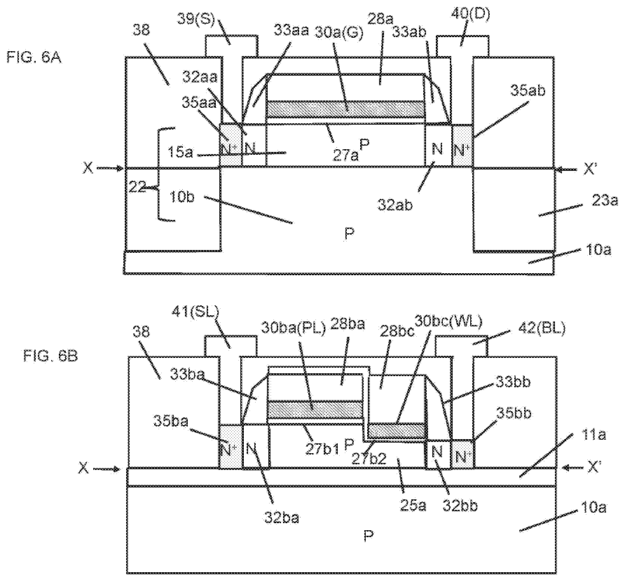

FIGS. 6A and 6B are structural sectional views according to the second embodiment in which a dynamic flash memory cell and a fin transistor are formed on the same P layer substrate 10a. FIG. 6A is a structural sectional view of the fin transistor and FIG. 6B is a structural sectional view of the dynamic flash memory cell. In FIGS. 6A and 6B, like elements in FIGS. 5A to 5MB are denoted by like reference signs. In the actual memory device, a large number of dynamic flash memory cells and a large number of fin transistors are formed on the substrate.

FIG. 6A illustrates the same structure as in the fin transistor of the logic circuit region illustrated in FIG. 5MA. In the dynamic flash memory cell in FIG. 6B, the upper surface of a fin P layer 25a surrounded by a gate conductor layer 30bc is positioned lower, in the perpendicular direction, than the upper surface of the fin P layer 25a surrounded by the gate conductor layer 30ba. For example, in the step illustrated in FIG. 5J, only the gate conductor layer 30ba connecting to the plate line PL of the dynamic flash memory cell is formed; subsequently, the word-line-WL-side upper portion of the fin P layer 25 is etched, to form the fin P layer 25a. Subsequently, a gate insulating layer 27b2 is formed so as to cover the word-line-WL-side fin P layer 25a, a side surface of the gate conductor layer 30ba, and the mask material layer 28ba. Between the gate conductor layer 30ba and the fin P layer 25a, a gate insulating layer 27b1 is disposed. Subsequently, the gate conductor layer 30bc connecting to the word line WL is formed. Note that the gate insulating layers 27a, 27b1, and 27b2 may be formed as layers that are different in material. The fin P layer 25a having the stepped structure may be formed after formation of the fin P layer 25 in FIG. 5I. The gate conductor layer 30bc and the gate conductor layer 30ba may be formed so as to be insulated from each other and overlap in plan view.

This embodiment has the following feature.

In this embodiment, for the fin P layer 25a surrounded by the gate conductor layer 30bc connecting to the word line WL, the upper surface of the fin P layer 25a surrounded by the gate conductor layer 30bc is positioned lower, in the perpendicular direction, than the upper surface of the fin P layer 25a surrounded by the gate conductor layer 30ba. This results in an increased volume of the fin P layer 25a surrounded by the PL gate conductor layer 30ba connecting to the plate line and used for storing signal charges and reduction in the contact between the fin P layer 25a and the N layer 32bb and the N⁺ layer 35bb, the contact being the cause of degradation of the “1” “0” characteristics due to occurrence of electron-hole recombination in the PN junction region or thermal-excitation generation of holes. This results in improvement in “1” “0” retention characteristics of the dynamic flash memory cell.

### Third Embodiment

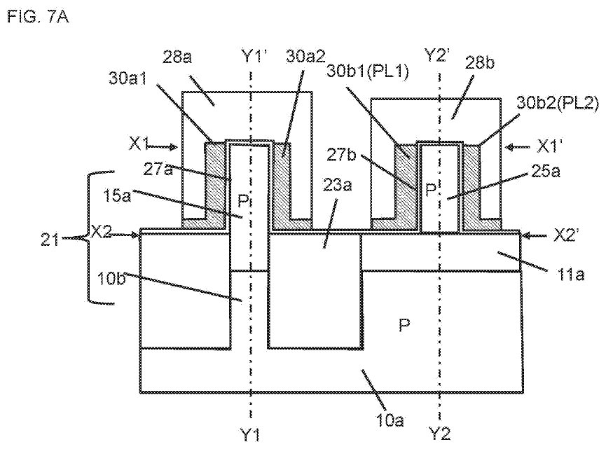

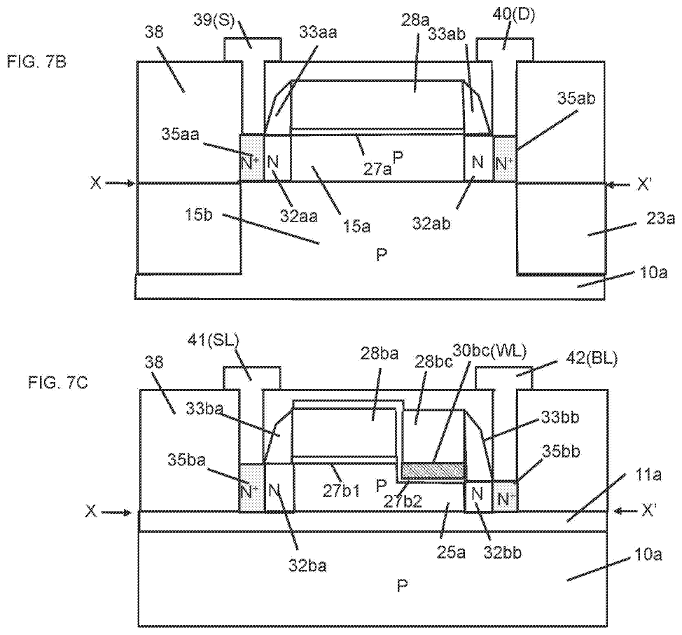

FIGS. 7A to 7C are structural sectional views according to the third embodiment in which a dynamic flash memory cell and a fin transistor are formed on the same P layer substrate 10a. FIG. 7A is a structural sectional view corresponding to FIG. 5J; FIGS. 7B and 7C are structural sectional views corresponding to FIGS. 6A and 6B. In the dynamic flash memory cell, the fin P layer and the gate conductor layer connecting to the word line WL are the same as the fin P layer 25a and the gate conductor layer 30bc in FIG. 6B. In FIGS. 7A to 7C, like elements in FIGS. 5A to 6B are denoted by like reference signs. In the actual memory device, a large number of dynamic flash memory cells and a large number of fin transistors are formed on the substrate.

In FIG. 6A, the gate conductor layer 30a connecting to the gate (G) is formed so as to cover the upper portion and both side surfaces of the fin P layer 15a; the gate conductor layer 30ba connecting to the plate line PL is also formed so as to cover the upper portion and both side surfaces of the fin P layer 25a. By contrast, as illustrated in FIGS. 7A, 7B, and 7C, the gate conductor layer 30a is formed on both side surfaces of the fin P layer 15a so as to be separated into gate conductor layers 30a1 and 30a2. Similarly, the gate conductor layer 30b connecting to the plate line PL is formed on both side surfaces of the fin P layer 25a so as to be separated into gate conductor layers 30b1 and 30b2. In this case, the upper surface of the gate conductor layer 30bc connecting to the word line WL is desirably positioned lower than the gate conductor-layer 30b1 or 30b2-side upper surfaces of the fin P layer 25. The gate conductor layers 30a1, 30a2, 30b1, and 30b2 are formed by, as illustrated in FIGS. 6A and 6B, forming the gate conductor layers 30a and 30ba and subsequently by performing CMP such that the upper surfaces of the gate conductor layers 30a and 30ba are polished to the level of the upper surfaces of the gate insulating layers 27a and 27b. Thus, in the logic circuit, a fin transistor including the gate conductor layers 30a1 and 30a2 separated from each other and disposed on both side surfaces of the fin P layer 15a is formed; in the memory cell region, a dynamic flash memory cell including the gate conductor layers 30b1 and 30b2 separated from each other and disposed on both side surfaces of the fin P layer 25a is formed.

This embodiment has the following feature.

In this embodiment, in the logic circuit, a fin transistor including the gate conductor layers 30a1 and 30a2 separated from each other and disposed on both side surfaces of the fin P layer 15a is formed; in the memory cell region, a dynamic flash memory cell including the gate conductor layers 30b1 and 30b2 separated from each other, disposed on both surfaces of the fin P layer 25a, and connecting to the plate lines PL1 and PL2 is formed. In the fin transistor including the separated gate conductor layers 30a1 and 30a2, a gate conductor layer out of the gate conductor layers 30a1 and 30a2 can be used as a threshold voltage control electrode. Thus, a fin transistor having a plurality of threshold voltages can be formed in the logic circuit region. In the dynamic flash memory cell, to the gate conductor layers 30b1 and 30b2 separated from each other, different voltage wave forms can be applied, to thereby improve operation characteristics.

### Fourth Embodiment

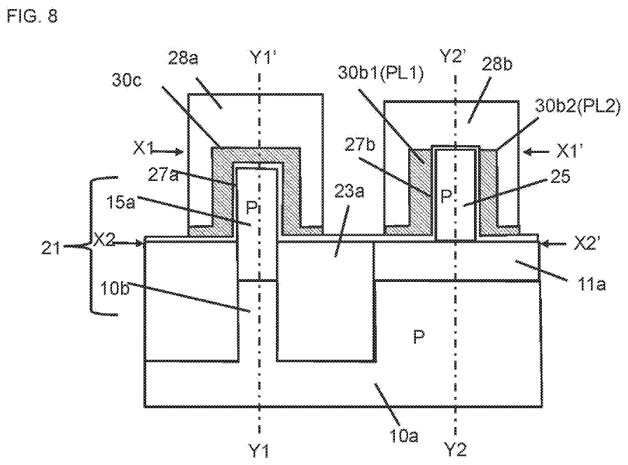

FIG. 8 is a structural sectional view according to the fourth embodiment in which a dynamic flash memory cell and a fin transistor are formed on the same P layer substrate 10a. This FIG. 8 is a structural sectional view corresponding to FIG. 7A.

As illustrated in FIG. 8, unlike FIG. 7A, the upper surface of the fin P layer 15a is positioned lower than the upper surface of the fin P layer 25 and, in the step of performing CMP to form the gate conductor layers 30b1 and 30b2 so as to be separated from each other, a gate conductor layer 30c surrounding the fin P layer 15a is left. As a result, in the fin transistor of the logic circuit region, the gate conductor layer 30c is formed so as to cover both side surfaces and the upper surface of the fin P layer 15a. In the dynamic flash memory cell, the gate conductor layers 30b1 and 30b2 are formed so as to be separated on both side surfaces of the fin P layer 25. The structure in which the upper surface of the fin P layer 15a is positioned lower than the upper surface of the fin P layer 25 can be easily achieved by increasing the thickness of the SiO₂ layer 17 formed by oxidizing the surface layer of the P layer 15 in FIG. 5D.

This embodiment has the following feature.

In this embodiment, the fin transistor disposed in the logic circuit and including the gate conductor layer 30c covering the entirety of the fin P layer 15a, and the dynamic flash memory cell disposed in the memory cell region and including the gate conductor layers 30b1 and 30b2 disposed so as to be separated from each other on both side surfaces of the fin P layer 25a and connecting to the plate lines PL1 and PL2 are formed on the same P layer substrate 10a. As a result, in the dynamic flash memory cell, to the gate conductor layers 30b1 and 30b2 separated from each other, different voltage wave forms can be applied, to thereby improve operation characteristics.

### Fifth Embodiment

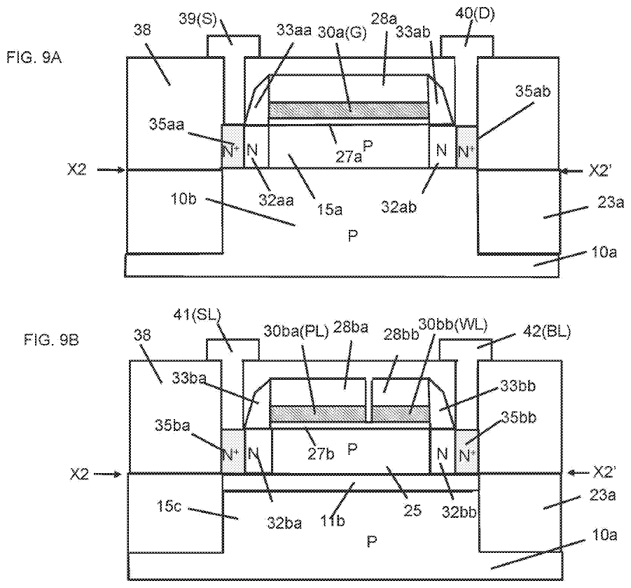

FIGS. 9A and 9B are structural sectional views according to the fifth embodiment in which a dynamic flash memory cell and a fin transistor are formed on the same P layer substrate 10a. FIGS. 9A and 9B are structural sectional views corresponding to FIGS. 5MA and 5MB.

The fin transistor in FIG. 9A is the same as in FIG. 5MA. By contrast, for the dynamic flash memory cell, as illustrated in FIG. 9B, in plan view, a SiO₂ layer 11b and a fin P layer 15c having the same shape as the region of the fin P layer 25, the N layers 32ba and 32bb, and the N⁺ layers 35ba and 35bb are formed.

This embodiment has the following feature.

In FIGS. 5F to 5H, the insulating layer 19a is used as an etching mask and the fin P layer 21 (refer to FIG. 5F) is formed; subsequently, the insulating layer 19ba is used as an etching mask and a fin P layer 25 (refer to FIG. 5H) is formed. By contrast, in this embodiment, the insulating layers 19a and 19ba serving as etching masks are simultaneously formed; the insulating layers 19a and 19ba are used as etching masks and RIE etching is performed to thereby simultaneously form the fin P layer 15b in the fin transistor and the fin P layers 15c and 25 and the SiO₂ layer 11b in the dynamic flash memory cell. This simplifies the steps.

### Sixth Embodiment

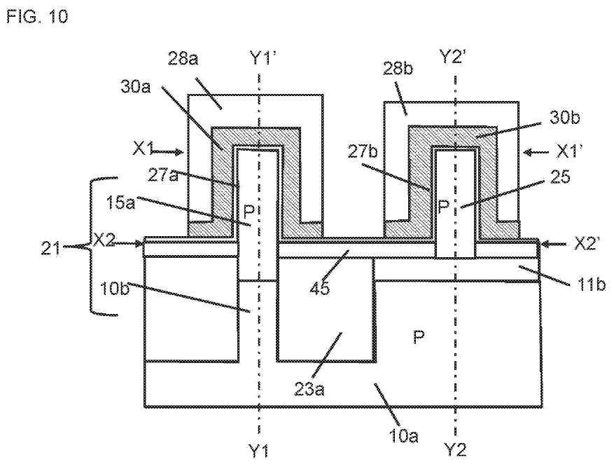

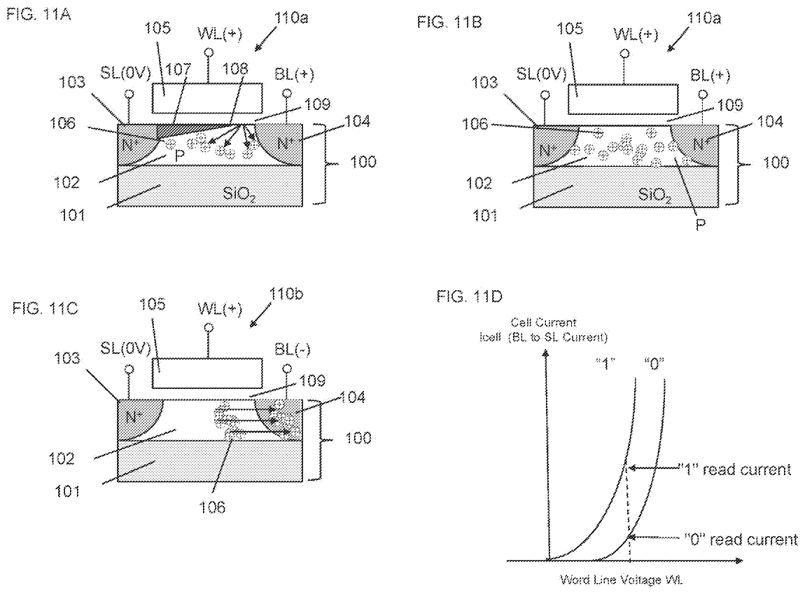

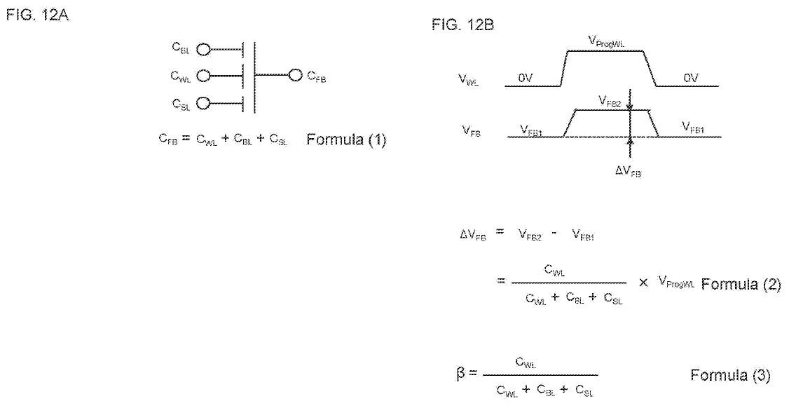

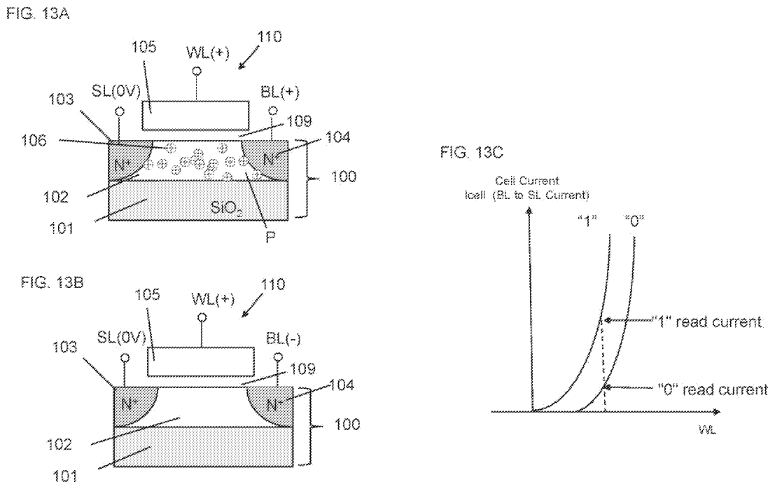

FIG. 10 is a structural sectional view according to the sixth embodiment in which a dynamic flash memory cell and a fin transistor are formed on the same P layer substrate 10a. FIG. 10 is a structural sectional view corresponding to FIG. 5J.

In FIG. 5J, the gate insulating layers 27a and 27b are formed so as to surround the upper portions of the fin P layers 15a and 25 and to be disposed over the SiO₂ layers 23a and 11a. By contrast, in this embodiment, as illustrated in FIG. 10, an insulating layer 45 is disposed so as to be over the SiO₂ layers 23a and 11a, to surround the fin P layers 15a and 25, and to be disposed under the gate insulating layers 27a and 27b. As a result, in the bottom portion of the fin P layer 25, a portion not surrounded by the gate conductor layer 30b is formed.

In this embodiment, in the bottom portion of the fin P layer 25, a portion not surrounded by the gate conductor layer 30b is formed. Thus, a large amount of holes retaining data “1” can be stored in the bottom portion of the fin P layer 25. This results in improvement in characteristics of the dynamic flash memory cell.

Note that, in FIGS. 5LA to 5MB, the longitudinal gate length of the gate conductor layer 30a of the fin transistor may be different from the gate lengths of the gate conductor layers 30ba and 30bb of the dynamic flash memory cell, in accordance with the design requirements. The same applies to other embodiments according to the present invention.

In FIGS. 5KA and 5KB, the N⁺ layers 35aa, 35ab, 35ba, and 35bb may be formed not only by the ion implantation process, but also by another process such as an epitaxial growth process. The same applies to other embodiments according to the present invention.

In FIGS. 5KA to 5MB, the sections of the fin P layers 15a, 10a, and 25 are illustrated as having rectangular shapes; alternatively, the sections may have trapezoidal shapes, for example. In FIG. 5I, after formation of the SiO₂ layer 23a, washing of the exposed fin P layer 15a causes, for example, formation of an oxide film in the exposed surface, which may result in, in the perpendicular direction, different shapes, with respect to the upper surface of the SiO₂ layer 23a, of the fin P layer 15a. The same applies to other embodiments according to the present invention.

Referring to FIG. 5F, FIG. 5I, and FIG. 5H, for example, in such a step in which the surfaces of the fin P layers 21 and 25 are exposed, in order to cover and protect the exposed surfaces of the fin P layers 21 and 25, for example, an ALD (Atomic Layer Deposition) process may be performed to form a protective film such as a SiO₂ layer. The same applies to other embodiments according to the present invention.

In FIGS. 1A and 1B, in order to make the gate capacitance of the first gate conductor layer 5a connected to the plate line PL be higher than the gate capacitance of the second gate conductor layer 5b to which the word line WL is connected, the gate length of the first gate conductor layer 5a is made larger than the gate length of the second gate conductor layer 5b. Alternatively, without making the gate length of the first gate conductor layer 5a be larger than the gate length of the second gate conductor layer 5b, the film thicknesses of the gate insulating layers may be changed such that the film thickness of the gate insulating film of the first gate insulating layer 4a is smaller than the film thickness of the gate insulating film of the second gate insulating layer 4b. The dielectric constants of the materials for the gate insulating layers may be changed such that the dielectric constant of the gate insulating film of the first gate insulating layer 4a is larger than the dielectric constant of the gate insulating film of the second gate insulating layer 4b. Some of these adjustments in the lengths of the gate conductor layers 5a and 5b, and the film thicknesses and dielectric constants of the gate insulating layers 4a and 4b may be combined such that the gate capacitance of the first gate conductor layer 5a connected to the plate line PL is higher than the gate capacitance of the second gate conductor layer 5b to which the word line WL is connected. Alternatively, the first gate conductor layer 5a may be divided into a plurality of layers in the perpendicular direction such that the gate capacitance of the first gate conductor layer 5a is higher than the gate capacitance of the second gate conductor layer 5b. The same applies to other embodiments according to the present invention.

In the first embodiment, during the erase operation, the source line SL is negatively biased, to extract hole groups within the first semiconductor layer 2 being a floating body FB; alternatively, instead of the source line SL, the bit line BL may be negatively biased or the source line SL and the bit line BL may be negatively biased, to perform the erase operation. Alternatively, under other voltage conditions, the erase operation may be performed. The same applies to other embodiments according to the present invention.

In FIGS. 5MA and 5MB, the metal wiring layers 39, 40, 41, and 42 are formed so as to extend over the SiO₂ layer 38; alternatively, the layers may extend at different levels in the perpendicular direction and over the insulating layer. The same applies to other embodiments according to the present invention.

For the present invention, without departing from the broad spirit and scope of the present invention, various embodiments and modifications can be made. The above-described embodiments are provided for the purpose of describing examples of the present invention and do not limit the scope of the present invention. The examples and modifications can be appropriately combined. In addition, the embodiments from which a portion of the features has been removed as needed also fall in the scope of the technical idea of the present invention.

Semiconductor memory devices according to embodiments of the present invention provide a high-performance dynamic flash memory and a logic circuit using a fin transistor that are disposed on the same substrate and produced at low costs.

What is claimed is:

1. A semiconductor memory device comprising:
a dynamic flash memory cell; and
a fin transistor,
wherein the dynamic flash memory cell includes
a first insulating layer on a semiconductor substrate,
a first fin semiconductor layer disposed on the first insulating layer and extending in a horizontal direction relative to the semiconductor substrate,
a first impurity region and a second impurity region that connect to both longitudinal sides of the first fin semiconductor layer,
a first gate insulating layer covering the first fin semiconductor layer,
a first gate conductor layer covering a portion of the first gate insulating layer, and
a second gate conductor layer that is adjacent to the first gate conductor layer and covers the first gate insulating layer,
the fin transistor includes
a second fin semiconductor layer that stands in a perpendicular direction relative to the semiconductor substrate and includes a bottom portion within the semiconductor substrate,
a third impurity region and a fourth impurity region that connect to both upper longitudinal sides of the second fin semiconductor layer,
a second gate insulating layer covering an upper surface and both side surfaces of an upper portion of the second fin semiconductor layer, and
a third gate conductor layer covering the second gate insulating layer,
in the perpendicular direction relative to the semiconductor substrate, a top portion of the first fin semiconductor layer is positioned close to a top portion of the second fin semiconductor layer,
in the perpendicular direction relative to the semiconductor substrate, bottom portions of the first gate insulating layer and the second gate insulating layer are positioned close to each other, and
in the perpendicular direction relative to the semiconductor substrate, the bottom portion of the second fin semiconductor layer is positioned within the semiconductor substrate.

2. The semiconductor memory device according to claim 1, wherein the second fin semiconductor layer includes a lower portion being a portion of the semiconductor substrate and an upper portion being a first semiconductor layer.

3. The semiconductor memory device according to claim 1, wherein the first gate insulating layer and the second gate insulating layer are layers formed of the same material.

4. The semiconductor memory device according to claim 1, wherein the third gate conductor layer is a layer formed of the same material as in one or both of the first gate conductor layer and the second gate conductor layer.

5. The semiconductor memory device according to claim 1, wherein, in the perpendicular direction relative to the semiconductor substrate, an upper surface of the first fin semiconductor layer surrounded by the first gate conductor layer is positioned above an upper surface of the first fin semiconductor layer surrounded by the second gate conductor layer.

6. The semiconductor memory device according to claim 5, wherein, in the perpendicular direction relative to the semiconductor substrate, an upper surface of the second gate conductor layer is positioned below a bottom surface of the first gate conductor layer.

7. The semiconductor memory device according to claim 1, wherein the first gate conductor layer includes a fourth gate conductor layer and a fifth gate conductor layer that are separated from each other and disposed on both side surfaces of the first fin semiconductor layer.

8. The semiconductor memory device according to claim 7, wherein the third gate conductor layer includes a fifth gate conductor layer and a sixth gate conductor layer that are separated from each other and disposed on both side surfaces of the second fin semiconductor layer.

9. The semiconductor memory device according to claim 7, wherein, in the perpendicular direction relative to the semiconductor substrate, an upper surface of the first fin semiconductor layer is positioned higher than an upper surface of the second fin semiconductor layer and an upper surface of the third gate conductor layer is positioned close to the upper surface of the first fin semiconductor layer.

10. The semiconductor memory device according to claim 1, wherein the first insulating layer has, in plan view, the same shape as the first fin semiconductor layer, and the semiconductor substrate connects to a bottom of the first insulating layer and includes an upper portion having, in plan view, substantially the same shape as the first fin semiconductor layer.

11. The semiconductor memory device according to claim 1, further comprising a second insulating layer surrounding a bottom portion of the first fin semiconductor layer, disposed over the first insulating layer, and disposed under the first gate insulating layer and the second gate insulating layer.

12. The semiconductor memory device according to claim 1, wherein a wiring line connecting to the first impurity region is a source line, a wiring line connecting to the second impurity region is a bit line, a wiring line connecting to the first gate conductor layer is a plate line, and a wiring line connecting to the second gate conductor layer is a word line, and
one of the first gate conductor layer and the second gate conductor layer connects to the word line and another one of the first gate conductor layer and the second gate conductor layer connects to the plate line.

13. The semiconductor memory device according to claim 1, wherein a first gate capacitance between the first gate conductor layer and the first fin semiconductor layer is higher than a second gate capacitance between the second gate conductor layer and the first fin semiconductor layer.

14. The semiconductor memory device according to claim 1, wherein the first impurity region and the second impurity region are N-type semiconductor layers containing a donor impurity at high concentration, and the first fin semiconductor layer is a P-type semiconductor layer containing an acceptor impurity.

15. The semiconductor memory device according to claim 1, wherein the semiconductor memory device is configured to control voltages applied to the first impurity region, the second impurity region, the first gate conductor layer, and the second gate conductor layer to perform an operation of using a current flowing between the first impurity region and the second impurity region to cause an impact ionization phenomenon or using a gate induced drain leakage current, to generate an electron group and a hole group in the first fin semiconductor layer, an operation of discharging, of the generated electron group and hole group, the electron group or hole group serving as a minority carrier from the first impurity region or the second impurity region, and an operation of causing a portion or entirety of the hole group or electron group serving as a majority carrier to remain within the first fin semiconductor layer, to perform a memory write operation, and
the semiconductor memory device is configured to control voltages applied to the first impurity region, the second impurity region, the first gate conductor layer, and the second gate conductor layer to perform an operation of removing, from one or both of the first impurity region and the second impurity region, of the hole group and electron group, a remaining hole group or a remaining electron group, to perform a memory erase operation.

16. The semiconductor memory device according to claim 1, wherein one or both of the first gate conductor layer and the second gate conductor layer are divided into two or more layers and the two or more layers are driven synchronously or asynchronously.
